(19) United States
(12) Patent Application Publication
(10) Pub. No.: US 2011/0080368 A1
(43) Pub. Date: Apr. 7, 2011

(54) Input device of touch screen and method of manufacturing the same

(75) Inventors: Jong Young Lee, Suwon (KR); Yongsoo Oh, Seongnam (KR); Ho Joon Park, Seoul (KR); Sang Hwa Kim, Suwon (KR); Sung Soo Park, Seongnam (KR); Woon Chun Kim, Suwon (KR)

(73) Assignee: SAMSUNG ELECTRO-MECHANICS CO., LTD., Suwon (KR)

(21) Appl. No.: 12/662,973

(22) Filed: May 13, 2010

(30) Foreign Application Priority Data
Oct. 1, 2009 (KR) 10-2009-0094104

(51) Int. Cl. G06F 3/045; H05K 3/10

(52) U.S. Cl. 345/174; 29/846

(57) ABSTRACT

There is provided an input device of a touch screen and a method of manufacturing the same. A input device of a touch screen according to an aspect of the invention may include: a first board and a second board arranged to face each other; a first conductive layer and a second conductive layer provided on the first board and the second board, respectively, while the first conductive layer and the second conductive layer face each other; and a zinc oxide thin film provided on the first conductive layer and aligned in a c-axis direction, wherein electrical changes in the zinc oxide thin film caused by mechanical deformation, applied to one region of the second conductive layer, are detected in the first conductive layer.

### CROSS-REFERENCE TO RELATED APPLICATIONS

This application claims the priority of Korean Patent Application No. 10-2009-0094104 filed on Oct. 1, 2009, in the Korean. Intellectual Property Office, the disclosure of which is incorporated herein by reference.

### BACKGROUND OF THE INVENTION

1. Field of the Invention

The present invention relates to an input device of a touch screen and a method of manufacturing the same, and more particularly, to an input device of a touch screen having excellent optical transparency and durability and a method of manufacturing the same.

2. Description of the Related Art

A touch screen refers to an input device that detects a location of a touch by a user on a display screen and performs the general control of electronic equipment, including the display screen control, on the basis of information about the detected contact location as input information.

A touch screen allows for the interactive manipulation of a computer with the use of a screen alone without prior knowledge of computers. A touch screen can replace an existing keyboard or mouse. According to this input method, new computer users can easily use computers.

Touch screens may be manufactured using various kinds of methods according to operating schemes thereof to manufacture, for example, resistive, capacitive, infrared beam, integral strain gauge, surface acoustic wave, and piezoelectric touch screens.

Resistive touch screens surpass other types of touch screens because of low manufacturing costs and a simplified mounting process for the recent development of digital input devices, such as home appliances, automobiles, communication devices and personal digital assistants (PDAs).

As for resistive touch screens, transparent conductive layers, facing each other, come into contact with each other by a user's touch, and then, a change in voltage flowing through upper and lower transparent conductive layers is detected to determine a location. These resistive touch screens are divided into 4-wire resistive touch screens and 5-wire resistive touch screens according to the electrode design.

A resistive touch screen has an upper board and a lower board arranged to face each other. Transparent conductive layers are coated over the upper and lower boards. Dot spacers are formed on the lower board to provide electrical isolation between the transparent conductive layers formed on the upper and lower boards. The upper and lower boards are sealed with an adhesive or an adhesive film.

As the upper conductive layer is repeatedly bent to drive the resistive touch screen, the upper conductive layer and the lower conductive layer eventually come to stick together. In addition, a lack of durability in the upper conductive layer causes cracks within the upper conductive layer.

Also, an air layer existing between the upper and lower boards reduces transmission and will likely lead to Newton's rings.

### SUMMARY OF THE INVENTION

An aspect of the present invention provides an input device of a touch screen having excellent light transmission and durability and a method of manufacturing the same.

According to an aspect of the present invention, there is provided an input device of a touch screen, the input device including: a first board and a second board arranged to face each other; a first conductive layer and a second conductive layer provided on the first board and the second board, respectively, while the first conductive layer and the second conductive layer face each other; and a zinc oxide thin film provided on the first conductive layer and aligned in a c-axis direction, wherein electrical changes in the zinc oxide thin film caused by mechanical deformation, applied to one region of the second conductive layer, are detected in the first conductive layer.

The zinc oxide thin film may be provided on the first conductive layer by a deposition process.

The zinc oxide thin film may have a thickness within a range of 0.01 to 10 μm.

At least one of the first conductive layer and the second conductive layer may be formed of a conductive polymer or a conductive inorganic material.

At least one of the first board and the second board may be formed of resin or glass.

According to another aspect of the present invention, there is provided a method of manufacturing an input device of a touch screen, the method including: forming a first conductive layer on a first board; forming a zinc oxide thin film, aligned in a c-axis direction, on the first conductive layer; and forming a second conductive layer and a second board on the zinc oxide thin film.

The zinc oxide thin film may be formed by a deposition process.

At least one of the first conductive layer and the second conductive layer may be formed by a printing method or a deposition method.

At least one of the first conductive layer and the second conductive layer may be formed of a conductive polymer or a conductive inorganic material.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically illustrating an input device of a touch screen according to an exemplary embodiment of the present invention;

FIGS. 2A and 2B are a plan view schematically illustrating a first conductive layer and a second conductive layer of an input device of a touch screen facing each other according to an exemplary embodiment of the present invention;

FIG. 3A through 3C are cross-sectional views illustrating the process flow of a method of manufacturing an input device of a touch screen according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

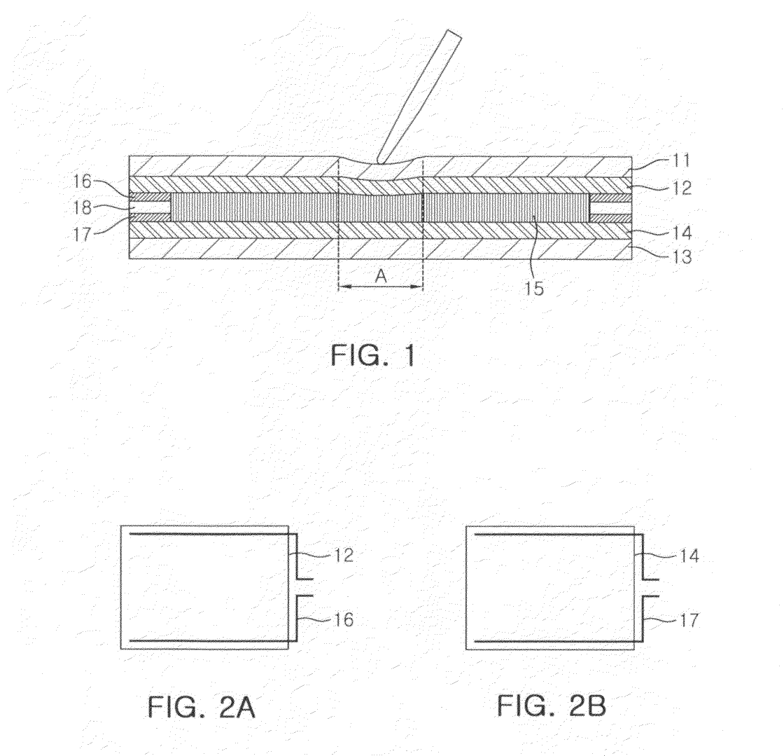

FIG. 1 is a cross-sectional view schematically illustrating an input device of a touch screen according to an exemplary embodiment of the invention. FIG. 2 is a plan view schematically illustrating a first conductive layer and a second conductive layer of an input device of a touch screen facing each other.

Referring to FIG. 1, an input device of a touch screen according to this embodiment includes a first board 13 and a second board 11 facing the first board 13.

The first and second boards 13 and 11 may have a thickness within the range of 10 to 1500 μm. However, the invention is not limited thereto.

The first and second boards 13 and 11 may be formed of resin or glass. The material thereof, however, is not particularly limited as long as it is easy to form a conductive layer on one surface of each of the first and second boards 13 and 11.

The resin is not particularly limited, and may be polyethylene terephthalate (PET), polycarbonate (PC), polymethylmethacrylate (PMMA), polyethylene naphthalate (PEN), polyethersulfone (PES) or a cyclic olefin polymer (COC).

The first and second boards 13 and 11 may be formed of colored or colorless materials according to the purpose. When the first board or the second board is provided as a display surface, a transparent material may be used therefor.

In this specification, being transparent may refer to being colorless transparent, colored transparent, translucent, and colored translucent.

A first conductive layer 14 is formed on one surface of the first board 13, while a second conductive layer 12 is formed on one surface of the second board 11 facing the first board 13.

Referring to FIGS. 2A and 2B, a first electrode 17 and a second electrode 16 are formed on the first conductive layer 14 and the second conductive layer 12, respectively, in order to detect electrical changes in a zinc oxide thin film to be described below. The locations at which the first electrode 17 and the second electrode 16 are formed are not particularly limited.

Furthermore, an insulating layer 18 is formed between the first and second electrodes. The insulating layer may be formed of an insulating adhesive or an insulating double sided film.

At least one of the first conductive layer 14 and the second conductive layer 12 may be formed of a conductive polymer or a conductive inorganic material.

The conductive polymer may be selected from, for example, polythiophene, polyanailine polyacetylene, polypyrrole, phenylenevinylene and derivatives thereof. However, the invention is not limited thereto.

In addition to the conductive polymer, at least one of the first conductive layer 14 and the second conductive layer 12 may further include carbon nanotubes (CNTs), graphene, silver (Ag) nanoparticles, copper (Cu), Indium Tin Oxide (ITO), and Antimony Tin Oxide (ATO).

The conductive inorganic material may use Indium Tin Oxide (ITO), Indium Zinc Oxide (IZO) or Aluminum Zinc Oxide (AZO). However, the invention is not limited thereto.

When the conductive polymer is used, the first and second conductive layers may be formed by a printing method such as gravure printing, screen printing or inkjet printing.

When the conductive inorganic material is used, the first and second conductive layers may be formed by deposition.

A zinc oxide (ZnO) thin film 15 is formed on the first conductive layer 14, and the second conductive layer 12 is formed to cover the zinc oxide thin film 15.

The zinc oxide thin film 15 is aligned in the c-axis direction and is formed on the first conductive layer 14 by deposition. The zinc oxide thin film 15 may have a thickness within the range of 0.01 to 10 μm. However, the invention is not limited thereto.

The zinc oxide thin film 15 is aligned in the c-axis direction and produces piezoelectric effects causing the polarization of potential difference by external pressure.

That is, mechanical deformation applied to the second conductive layer 12 caused by a user's touch leads to electrical changes in the zinc oxide thin film 15.

The zinc oxide thin film 15 is aligned in the c-axis direction and can detect local changes in mechanical pressure without undergoing separate etching or partitioning. A voltage difference occurs locally.

As shown in FIG. 1, mechanical deformation applied to a region A of the second conductive layer leads to electrical changes in one region of the zinc oxide thin film. These electrical changes are noticed in the first conductive layer. The electrical changes noticed in the first conductive layer are detected by the first electrode 17 and the second electrode 16. Therefore, the location of the touch can be detected.

In the related art, the air layer is formed between the upper conductive layer and the lower conductive layer, and dot spacers are formed on the lower conductive layer to provide electrical insulation between the upper conductive layer and the lower conductive layer.

As the upper conductive layer is repeatedly bent to drive the resistive touch screen, the upper conductive layer and the lower conductive layer eventually come to stick together. In addition, a lack of durability in the upper conductive layer causes cracks within the upper conductive layer.

As the upper conductive layer is repeatedly bent, cracks occur in the corners of the upper conductive layer, on which the load is concentrated, due to a lack of durability.

However, according to this embodiment, since an air layer does not exist between the first conductive layer 14 and the second conductive layer 12, and the zinc oxide thin film is formed, the amount of bending deflection of the second conductive layer is insignificant. Therefore, there is less possibility that the first conductive layer and the second conductive layer may come into contact with each other or that cracks may occur.

In the related art, the air layer between the upper board and the lower board increases an interlayer refractive index difference, thereby reducing transmission and likely causing Newton's rings.

However, in this embodiment, the interlayer refractive index difference between layers forming the input device of a touch screen is small to thereby reduce reflectivity and increase optical transmission.

The refractive index and the light extraction efficiency of the input device of a touch screen according to this embodiment and the input device of the touch panel in the related art are shown in Table 1 below. Examples of the input device of a touch screen according to this embodiment include an example using PET boards and conductive layers formed of a conductive polymer, an example using PET boards and ITO conductive layers, and an example using PET boards and a conductive layer formed of a conductive polymer and an ITO conductive layer.

TABLE 1

| | | MEDIUM | MEDIUM | | | | LIGHT |
|---|---|---|---|---|---|---|---|
| | | REFRACTIVE | REFRACTIVE | n = n₂/ | CRITICAL | | EXTRACTION |
| CLASSIFICATION | | INDEX n₁ | INDEX n₁ | n₁ | ANGLE θc | REFLECTIVITY | EFFICIENCY |
| Dot | PET- | 1.66 | 1.95 | 1.17 | | 0.0065 | |
| spacer | ITO | | | | | | |
| | ITO- | 1.95 | 1.00 | 0.51 | 31 | 0.1037 | 7 |
| | PACKAGE | | | | | | |
| | air | | | | | | |
| | PACKAGE | 1.00 | 1.95 | 1.95 | | 0.1037 | |
| | air- | | | | | | |
| | ITO | | | | | | |
| | ITO- | 1.95 | 1.66 | 0.85 | 58 | 0.0065 | 18 |
| | PET | | | | | | |
| | PET- | 1.66 | 1.00 | 0.60 | 37 | 0.0616 | 9 |
| | Air | | | | | | |
| PIEZOELECTRIC | PET- | 1.66 | 1.47 | 0.89 | 62 | 0.0037 | 20 |
| THIN | CONDUCTIVE P | | | | | | |
| FILM | CONDUCTIVE P- | 1.47 | 2.00 | 1.36 | | 0.0233 | 46 |
| ZnO | ZnO | | | | | | |
| | ZnO | 2.00 | 1.47 | 0.74 | 47 | 0.0233 | |
| | CONDUCTIVE P | | | | | | |
| | CONDUCTIVE P- | 1.47 | 1.66 | 1.13 | | 0.0037 | |
| | PET | | | | | | |
| | PET- | 1.66 | 1.00 | 0.60 | 37 | 0.0616 | 9 |
| | Air | | | | | | |
| PIEZOELECTRIC | PET- | 1.66 | 1.95 | 1.17 | | 0.0065 | 34 |
| THIN | ITO | | | | | | |
| FILM | ITO- | 1.95 | 2.00 | 1.03 | | 0.0002 | 26 |
| ZnO | ZnO | | | | | | |
| | ZnO- | 2.00 | 1.95 | 0.98 | 77 | 0.0002 | |
| | ITO | | | | | | |
| | ITO- | 1.95 | 1.66 | 0.85 | 58 | 0.0065 | 9 |
| | PET | | | | | | |
| | PET- | 1.66 | 1.00 | 0.60 | 37 | 0.0616 | 9 |
| | Air | | | | | | |
| PIEZOELECTRIC | PET- | 1.66 | 1.95 | 1.17 | | 0.0065 | 34 |
| THIN | ITO | | | | | | |
| FILM | ITO- | 1.95 | 2.00 | 1.03 | | 0.0002 | 26 |
| ZnO | ZnO | | | | | | |
| | ZnO- | 2.00 | 1.47 | 0.74 | 47 | 0.0233 | |
| | CONDUCTIVE P | | | | | | |
| | CONDUCTIVE P- | 1.47 | 1.66 | 1.13 | | 0.0037 | |
| | PET | | | | | | |
| | PET- | 1.66 | 1.00 | 0.60 | 37 | 0.0616 | 9 |
| | Air | | | | | | |

Referring to Table 1, the input device of a touch screen according to the invention has low reflectivity because of a small interlayer refractive index difference and has excellent light extraction efficiency.

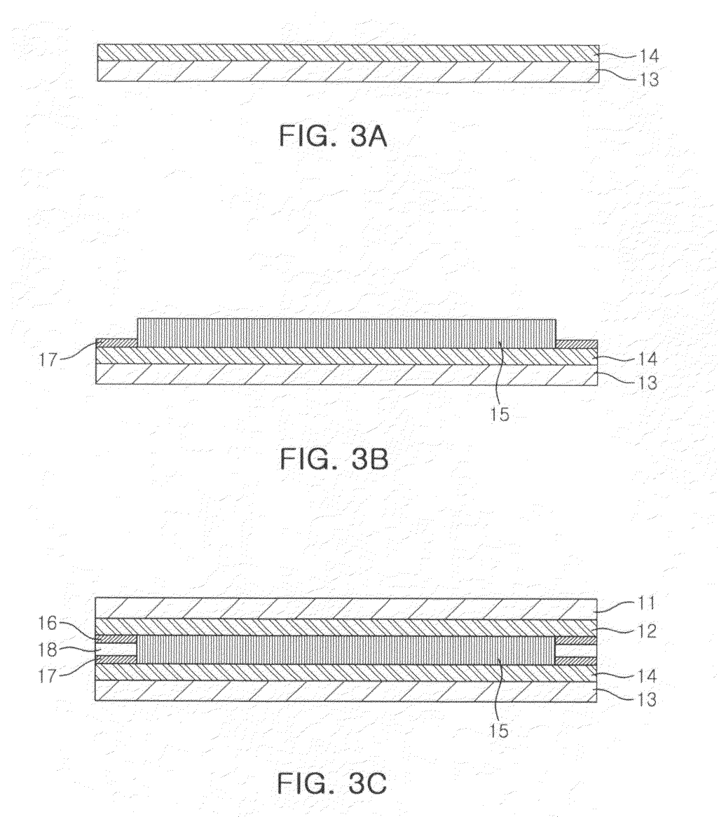

Hereinafter, a method of manufacturing an input device of a touch screen according to an exemplary embodiment of the invention will be described with reference to FIGS. 3A through 3C.

FIGS. 3A through 3C are cross-sectional views illustrating the process flow of a method of manufacturing an input device of a touch screen according to an exemplary embodiment of the invention.

First, the first conductive layer 14 is formed on the first board 13. The first board 13 and the first conductive layer 14 are formed of materials as described above.

As described above, when the first conductive layer 14 is formed of a conductive polymer, the first conductive layer 14 may be formed using a printing method. When the first conductive layer 14 is formed of a conductive inorganic material, the first conductive layer 14 may be formed using a deposition method.

Then, as shown in FIG. 3B, the first electrode 17 and the zinc oxide thin film 15, aligned in the c-axis direction, are formed on the first conductive layer 14.

The zinc oxide thin film 15 is formed on the first conductive layer by a deposition process. As the zinc oxide thin film 15 is formed by a deposition process, an air layer is not interposed between the first conductive layer 14 and the zinc oxide thin film 15. The first conductive layer and the zinc oxide thin film may be completely bonded to each other.

Furthermore, as the zinc oxide thin film 15 is not etched or patterned, and is formed on the entire surface of the first conductive layer 14, it is easy to form the insulating layer 18 between the first conductive layer 14 and the second conductive layer 12.

According to this embodiment, the zinc oxide thin film is aligned in the c-axis direction and can detect changes in local mechanical pressure. A voltage difference occurs locally.

Therefore, a separate etching process is not required to partition the zinc oxide thin film.

Then, as shown in FIG. 3C, the second conductive layer 12 is formed on the zinc oxide thin film 15. The second electrode 16 may be formed on the second conductive layer 12. Furthermore, the insulating layer 18 is formed between the first and second electrodes. The insulating layer 18 may be formed using an insulating adhesive or an insulating double sided film.

As described above, when the second conductive layer 12 is formed of a conductive polymer, the second conductive layer 12 may be formed using a printing method. When the second conductive layer 12 is formed of a conductive inorganic material, the second conductive layer 12 may be formed using a deposition method.

At this time, an air layer may not be interposed between the second conductive layer 12 and the zinc oxide thin film 15.

Then, the second board may be formed on the second conductive layer 12.

However, the invention is not limited thereto. The second conductive layer is formed on the second board, which may then be formed on the zinc oxide thin film.

As set forth above, according to exemplary embodiments of the invention, in an input device of a touch screen, as the zinc oxide thin film is formed between the first conductive and the second conductive layer, the amount of bending deflection of the second conductive layer is insignificant. Therefore, there is less possibility that the first conductive layer and the second conductive layer come into contact with each other or that cracks may occur.

Furthermore, as a refractive index difference between layers forming an input device of a touch screen is insignificant, reflectivity is low and light transmission is excellent.

While the present invention has been shown and described in connection with the exemplary embodiments, it will be apparent to those skilled in the art that modifications and variations can be made without departing from the spirit and scope of the invention as defined by the appended claims.

What is claimed is:

1. An input device of a touch screen, the input device comprising:
a first board and a second board arranged to face each other;
a first conductive layer and a second conductive layer provided on the first board and the second board, respectively, while the first conductive layer and the second conductive layer face each other; and
a zinc oxide thin film provided on the first conductive layer and aligned in a c-axis direction,
wherein electrical changes in the zinc oxide thin film caused by mechanical deformation, applied to one region of the second conductive layer, are detected in the first conductive layer.

2. The input device of claim 1, wherein the zinc oxide thin film is provided on the first conductive layer by a deposition process.

3. The input device of claim 1, wherein the zinc oxide thin film has a thickness within a range of 0.01 to 10 μm.

4. The input device of claim 1, wherein at least one of the first conductive layer and the second conductive layer is formed of a conductive polymer or a conductive inorganic material.

5. The input device of claim 1, wherein at least one of the first board and the second board is formed of resin or glass.

6. A method of manufacturing an input device of a touch screen, the method comprising:
forming a first conductive layer on a first board;
forming a zinc oxide thin film, aligned in a c-axis direction, on the first conductive layer; and
forming a second conductive layer and a second board on the zinc oxide thin film.

7. The method of claim 6, wherein the zinc oxide thin film is formed by a deposition process.

8. The method of claim 6, wherein at least one of the first conductive layer and the second conductive layer is formed by a printing method or a deposition method.

9. The method of claim 6, wherein at least one of the first conductive layer and the second conductive layer is formed of a conductive polymer or a conductive inorganic material.
